(19) United States
(12) Patent Application Publication
(10) Pub. No.: US 2009/0138217 A1
(43) Pub. Date: May 28, 2009

(54) TEST METHOD AND DEVICE FOR TESTING A PLURALITY OF RFID INTERPOSERS

(75) Inventor: Henrik Bufe, Leipzig (DE)

Correspondence Address: BLACK LOWE & GRAHAM, PLLC, 701 FIFTH AVENUE, SUITE 4800, SEATTLE, WA, 98104, US

(73) Assignee: MUEHLBAUER AG, Roding (DE)

(21) Appl. No.: 12/296,910

(22) PCT Filed: Apr. 5, 2007
(86) PCT No.: PCT/EP2007/053350

§ 371 Date: Oct. 10, 2008

(30) Foreign Application Priority Data
Apr. 12, 2006 (DE) 10 2006 017 656.1
Feb. 13, 2007 (DE) 10 2007 006 967.9

(51) Int. Cl. G01R 31/00

(52) U.S. Cl. 702/58

(57) ABSTRACT

Method for testing a large number of RFID interposers in order to check their functionality by means of a test device (9a-9c, 10, 12). Each interposer includes at least one RFID chip (6) and at least two enlarged connection surfaces (7a, 7b) which are arranged on an interposer substrate (8) and are connected to the RFID chip (6). A capacitive coupling for transmitting data is set up between the test device (9a-9c, 10, 12) and at least one of the interposers.

The invention relates to a test method and an apparatus for a large number of RFID interposers in order to check their functionality by means of a test device, wherein each interposer comprises at least one RFID chip and at least two enlarged connection surfaces which are arranged on an interposer substrate and are connected to the RFID chip, according to the preambles of claims 1 and 6.

Interposers or straps, which consist of an RFID chip and enlarged connection surfaces and a substrate and which are arranged in rows on a strip, are often wound in rows onto a roll after they have been produced in a production apparatus intended for this purpose. Such interposers or straps are often coated with additive adhesives or auxiliary materials or are provided with dirt that has been deposited in the interim before they are arranged in a further production apparatus, which served to connect the interposers or straps to antennas arranged on further substrates so as to produce so-called RFID labels or smart labels.

Before the interposers or straps are joined to the antennas in such production apparatuses, usually a test method is carried out in a test apparatus integrated in the production apparatus, during which the individual interposers are checked with regard to their functionality quickly, simply and in large numbers. To this end, use has to date been made of test apparatuses and test methods which make use of test heads with contact needles for contacting the straps or interposers. Such contact needles contact the enlarged connection surfaces of the individual interposer with very high rapidity in order to achieve a high throughput of the test apparatus by establishing mechanical contact with the connection surfaces in order to introduce a sufficient high-frequency energy into the RFID chip. The sufficient high-frequency energy is required in order to supply internal circuits of the RFID chip with sufficient energy. This is a prerequisite for the testing process, in particular in the form of reading the chip memory, and thus for checking the functionality of the individual RFID chip. Usually, internal identification numbers of the individual RFID chip are read in order to check the function of the chip.

Such mechanically contacting test heads in the form of needle heads mean that the individual needle tips cause damage to the connection surfaces of the interposers, which may be disadvantageous for the subsequent processing step since an electrically conductive contact with the antenna may not be able to be set up successfully.

Furthermore, such needle tips can be arranged only at a limited spatial distance from one another since even with the needle-type configuration they have a similar size in the region of the needle tip ends. This may lead to malfunctions when carrying out the test method since the two needles are either not spaced far enough apart from one another or else targeted meeting of the connection surfaces for placing the needle test head onto the individual interposers is not always ensured with a high degree of rapidity due to the test method to be carried out for a large number of interposers.

Furthermore, such needle test heads have a limited rapidity due to their mechanical configuration, since such needle test heads must firstly be lowered and then raised again in order to bring out the mechanical and electrical contact with the connection surfaces. For a large number of interposers to be tested, this leads to test times which can be reduced only to a limited extent, as a result of which the throughput of the production apparatus as a whole is reduced.

Moreover, such needle test heads are subject to wear when used frequently and also become soiled, which along with dirt on the interposer connection surfaces and the additive adhesives or auxiliaries arranged thereon makes it more difficult to achieve electrical and mechanical contacting by the needle tips.

Accordingly, the object of the preset invention is to provide a test method and a test apparatus for testing the functionality of a large number of RFID interposers, which makes it possible in a reliable manner to check a large number of interposers with a short test time without damaging the connection surfaces of the interposers and without any wear of the test apparatus.

### SUMMARY

This object is achieved in terms of the method by the features of claim 1 and in terms of the apparatus by the features of claim 6.

The core concept of the invention is that, in a test method for testing a large number of RFID interposers in order to check their functionality by means of a test device, wherein each interposer comprises at least one RFID chip and at least two enlarged connection surfaces which are arranged on an interposer substrate and are connected to the RFID chip, a capacitive coupling for transmitting data is set up between the test device and at least one of the interposers. By means of such a capacitive coupling, it is not just a mechanical, contactless connection that is set up between the test device and the interposer to be tested or the RFID chip integrated therein, so that wear phenomena as in the case of the previously used needle tips can be avoided, but rather a rapid and simple reading and/or writing of data from the chip and/or to the chip is also advantageously obtained. It is thus possible in a simple manner to avoid any damage to the connection surfaces of the interposer, which would take place if needle tips were used to contact these connection surfaces mechanically.

By using a capacitive coupling, given suitable dimensions of the coupling capacitor surfaces which are arranged as electrically conductive surfaces on the test device and to which the sizes of the connection surfaces of the interposers are matched, a respective capacitor can be formed between one of the connection surfaces and a coupling capacitor surface, so that spatial and capacitive separation of the capacitors is possible in a simple manner. An interposer with two connection surfaces thus forms a total of two capacitors with two coupling capacitor surfaces of the test device. This prevents the mutual influencing of the needle tips that often previously took place, which needle tips would have to be configured precisely such that they allow separate contacting of the closely adjacent connection surfaces of an interposer.

Such a capacitive coupling moreover reliably ensures a read and/or write connection to each of the interposers, which can be tested in succession or else simultaneously, even when the connection surfaces and optionally the RFID chip of the interposer has been provided with an adhesive layer and/or auxiliary layer as is often the case with interposers produced beforehand in a separate processing step.

The fact that raising and lowering of a needle test head is no longer necessary permits much shorter test times per interposer, so that the machine throughput of the production apparatus as a whole can be increased.

Preferably, a respective connection surface of a given interposer and a respective coupling capacitor surface of the test device have the same dimensions, wherein both surfaces are arranged opposite one another and parallel to one another in order to form a respective capacitor.

Alternatively, the coupling capacitor surfaces may be configured in such a way that a common strip-like continuous coupling capacitor surface is provided on a common substrate for a large number of connection surfaces arranged on the left-hand side of a large number of interposers, whereas separate coupling capacitor surfaces of equal size are provided for the connection surfaces on the right-hand side. This permits a separate or simultaneous actuation of the individual interposers for reading data, such as an ID number of the RFID chip for example.

The at least two connection surfaces of the interposers or straps, which are provided as flat electrically conductive connections for subsequent contacting with an RFID antenna to form a transponder, form a capacitive coupling with the coupling capacitor surfaces of the test device in order to form capacitors which have the interposer substrate arranged therebetween as dielectric. This is made possible by the fact that the test device is arranged below the interposers with the interposer substrates on the bottom, wherein the interposer substrate, which may comprise a large number of interposers, can be displaced with respect to the test device or vice versa, in parallel therewith, in order to test further interposers. To this end, the test apparatus according to the invention which includes the test device preferably has vacuum channels and cavities which are intended to serve to fix and then release the interposer substrate(s) with respect to the test device in order to test the following interposers in a further operating step.

The reading and writing of the RFID chip takes place by means of at least one reading and/or writing unit which serve to receive and/or transmit high-frequency RFID signal data in order to communicate with the RFID chips of the interposers. The interposers may be actuated in succession and/or simultaneously.

The capacitive coupling between the connection surfaces of the interposers and the coupling capacitor surfaces of the test device, based on Maxwell's electromagnetic field equations, is defined by the sizes of the opposite surfaces, the distance and angle between them and the properties of the material located between these surfaces which is passed through by the electric field. A resulting coupling capacitance between the surfaces can be calculated beforehand and used accordingly.

In the case of an AC current, the capacitors using the coupling capacitance form a capacitive reactance which becomes smaller as the capacitance increases and the frequency rises.

The test apparatus according to the invention advantageously comprises the test device with a layer structure composed of a control device, at least one plate-shaped substrate arranged thereon and coupling capacitor surfaces arranged on the substrate, wherein at least one interposer is arranged on the coupling capacitor surfaces with the interposer substrate facing towards the coupling capacitor surfaces. The control device serves to actuate the various coupling capacitor surfaces separately or simultaneously, in order to actuate and read in succession or simultaneously at least a selected group of the interposers arranged on a common interposer substrate.

The plate-shaped substrate preferably has a large number of coupling capacitor surfaces on which the large number of interposers are placed, wherein the data of the RFID chips of the interposers can be read and/or written to in succession and/or at least partially simultaneously by means of the control device and the reading and/or writing units.

Further advantageous embodiments emerge from the dependent claims.

### BRIEF DESCRIPTION OF THE DRAWINGS

Advantages and expedient features can be found in the following description in conjunction with the drawing. In the drawing:

FIG. 1 shows an equivalent circuit diagram for the mode of operation of the capacitive coupling according to the test method;

FIG. 2 shows a further equivalent circuit diagram for the mode of operation of the capacitive coupling according to the test method;

FIG. 3 shows, in a schematic cross-sectional diagram, the test apparatus according to one embodiment of the invention;

FIG. 4 shows, in a plan view, coupling capacitor surfaces of the test device and an interposer arranged on the test device;

FIG. 5 shows, in a cross-sectional diagram, the test apparatus according to a second embodiment of the invention, and

FIG. 6 shows, in a plan view, the test apparatus according to the second embodiment of the invention.

### DETAILED DESCRIPTION OF THE INVENTION

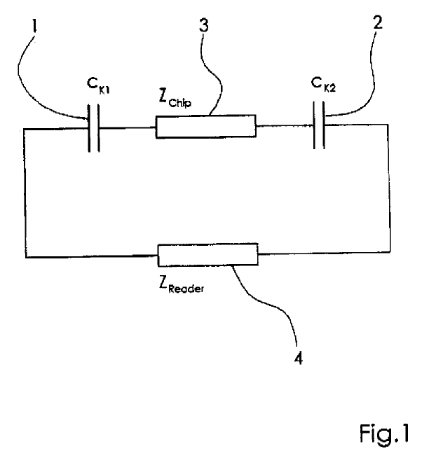

FIG. 1 shows an equivalent circuit diagram of the mode of operation of the test method. In a capacitive coupling set up according to the invention between coupling capacitor surfaces arranged on a test device and connection surfaces of interposers, there is produced a first capacitor 1 which is composed of the left-hand connection surface of an interposer and an associated coupling capacitor surface of the test device which is preferably of equal size.

Also produced is a second capacitor 2 which is composed of the right-hand connection surface of the interposer and an associated coupling capacitor surface of the test device which is preferably of equal size.

For an AC current, the capacitors form a capacitive reactance which becomes smaller and smaller as the capacitance increases and the frequency rises. A formula for calculating the capacitance of a plate capacitor is as follows:

$$C = ɛ o \cdot ɛ r \cdot \frac{A}{D} .$$

The formula for calculating capacitive reactances as a function of frequency is as follows:

$$Xc = \frac{1}{( 2 \cdot ω \cdot c )} .$$

The resulting equivalent circuit diagram, which is shown in FIG. 1, is also composed of the resistance 3 of the RFID chip and the resistance 4 of a reading and writing unit of the test device, which is connected in parallel.

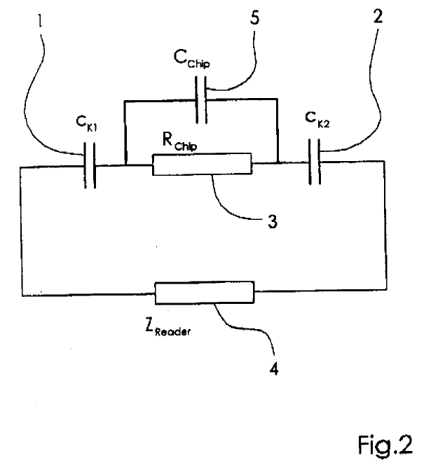

FIG. 2 shows a further equivalent circuit diagram of the mode of operation of the method. The capacitors 1 and 2 correspond to the capacitors composed of the connection surfaces of an interposer and associated coupling capacitor surfaces. The resistance 3 again denotes the resistance of the RFID chip. The resistance 4 again refers to the resistance of the reading and writing unit of the test device. A further capacitor 5 is shown.

During communication between the test device and one or more interposers via the capacitive coupling by means of RFID in the UHF range, frequencies between 850 and 930 MHz are used. At these frequencies, small capacitances of a few picofarads already form very low-ohmic capacitive reactances in the range of 0.1-500 Ω.

Between the RFID chip and a transponder antenna to be arranged subsequently, a coupling with the correct impedance is desired in order to make the maximum possible energy available to the RFID chip for operation. For this reason, the RFID chip and the antenna of the transponder operate in the so-called matched mode, i.e. the antenna impedance is equal to the chip input impedance. Only in this state is the maximum energy transport between the transponder antenna and the chip and thus the maximum range of the RFID UHF transponder system obtained.

Due to this mode of operation, input resistances for the RFID chip are obtained which are relatively low-ohmic and have a capacitive reactive component through the internal buffer capacitor of the chip circuit.

The orders of magnitude of these chip input resistances are in the range of approx. 8-90Ω with a capacitive reactive component of approx. −j20 to −j900Ω. The input resistances of the RFID chip therefore lie in a low-ohmic range and all the sources which are to supply the chip with energy must also have a low-ohmic impedance.

In the case of a contactless test method, it is clear that there should be a low-ohmic coupling capacitance between the metallic conductive surfaces of the straps or interposers and the coupling-in device or test device with the reading and writing device, in order to obtain an energy transport path with the smallest possible losses. It is clear from the equivalent circuit diagrams presented above that the contactless coupling is a series connection of two coupling capacitors and the equivalent circuit diagram of the RFID chip.

With such a series connection of capacitors, the added total capacitance is accordingly smaller than the smallest individual capacitance of one of the capacitors involved, as follows:

$$\frac{1}{{C}_{total}} = \frac{1}{{C}_{1}} + \frac{1}{{C}_{2}} + \frac{1}{{C}_{3 }} …$$

For the reasons given above, the aim should be the highest possible coupling capacitance and the highest possible operating frequency of the test device and thus of the test apparatus.

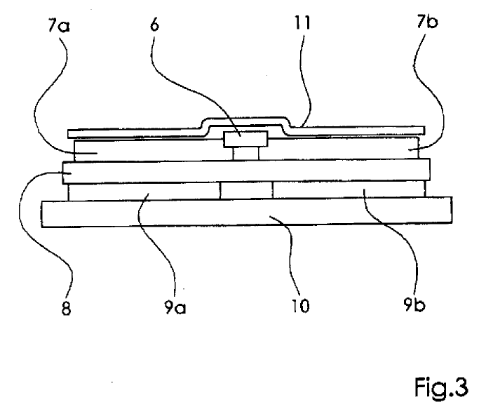

FIG. 3 shows, in a schematic cross-sectional diagram, the structure of an interposer to be tested with a test device arranged below it. For the capacitive coupling, a coupling takes place between on the one hand the connection surfaces 7a and 7b of the interposer, which has an RFID chip 6 connected to the connection surfaces at the top, and on the other hand coupling capacitor surfaces 9a and 9b which are separate from one another and are assigned to the connection surfaces 7a and 7b and are arranged on a substrate 10. Arranged between the connection surfaces 7a and 7b and the coupling capacitor surfaces 9a and 9b is an interposer substrate 8 on which the connection surfaces 7a and 7b are formed.

In addition, an additive adhesive layer or auxiliary layer 11 usually covers the top of the connection surfaces 7a and 7b and the RFID chip.

For the capacitive coupling between the connection surfaces 7a and 7b and the coupling capacitor surfaces 9a and 9b, which is set up by the formation of the capacitors, high-frequency energy is coupled into the conductive flat structures of the interposers, i.e. into the connection surfaces. To this end, advantageously the coupling capacitor surfaces 9a and 9b used may be structures in the form of pads, microstrip lines or other types of surfaces which have a defined conductivity. These surfaces in each case represent one side of the coupling capacitors for coupling the high-frequency energy into the interposers.

The metallic surfaces are arranged in a manner isolated from one another as coupling capacitor surfaces on the substrate material 10, which may consist for example of a PCB (printed circuit board). It is possible to use any other substrate material which can be used for the frequency range in question.

Plate capacitors constructed in this way have defined dimensions and fixed capacitances. The interposer substrate 8 serves as dielectric. Such a substrate usually consists of heat-stabilised PET or suchlike materials. Paper may also be used as the substrate material. The thickness of such a substrate material is generally between 30 and 70 μm.

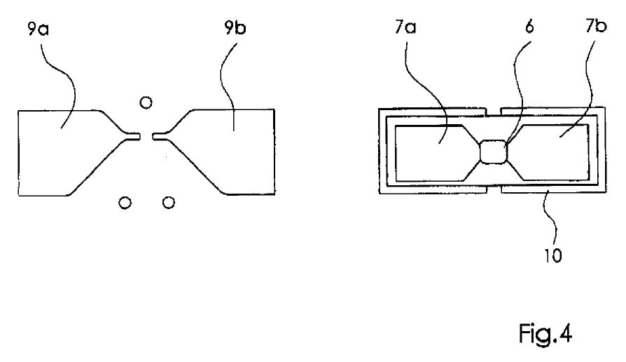

The left-hand side of FIG. 4 shows by way of example, in a plan view, how such coupling capacitor surfaces which are arranged on the substrate material of the test device may be formed. The right-hand side of FIG. 4 shows, in a plan view, the structure shown in FIG. 3, wherein the substrate 10 is arranged on the bottom with the coupling capacitor surfaces 9a, 9b arranged thereon and the interposer arranged thereon with the interposer substrate 8, the connection surfaces 7a and 7b and the RFID chip 6.

Customary surface areas of the connection surfaces which form the coupling capacitors are for example 9×4 mm. Such a size results in a capacitor plate surface area of approx. 9 mm² (3×3 mm). When using an interposer substrate material with a thickness of for example 50 μm, this therefore results in a plate spacing of 50 μm. The usable frequency of 900 MHz and a ∈r value of 3.5 for the interposer substrate material thus gives a capacitance value of the coupling capacitor of 5.58 pF. A reactance of 31.69Ω for each coupling capacitor can thus be calculated.

Due to the series connections of the two coupling capacitors which is shown in the equivalent circuit diagram in FIG. 2, an equivalent series resistance of 63.38Ω is therefore obtained. The real part of the input impedance of a UHF RFID chip is in the range from 8-90 Ω.

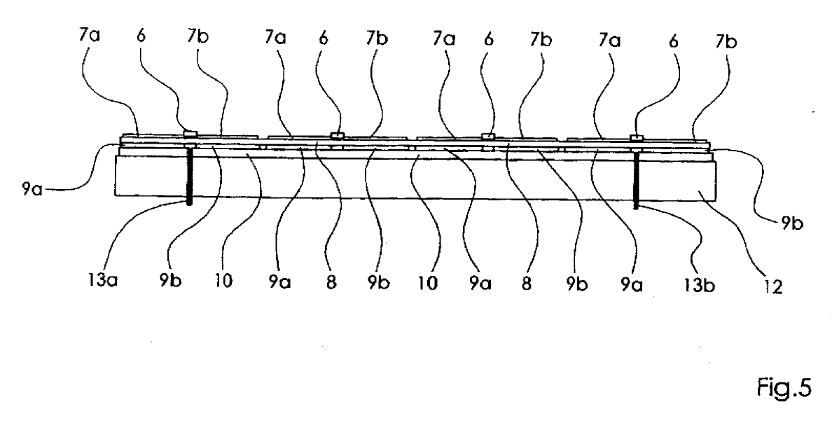

FIG. 5 shows, in a schematic cross-sectional diagram, a test apparatus according to a second embodiment of the invention. This test apparatus is composed of a control device 12, the substrate 10 arranged thereon, the plurality of coupling capacitor surfaces 9a, 9b arranged thereon, the interposer substrate 8, the connection surfaces 7a, 7b arranged thereon and the RFID chip 6. It can clearly be seen from this diagram that a plurality of interposers can be arranged on the test device.

The control device 12 serves to actuate the individual interposers separately or at least partially simultaneously by means of reading and writing units (not shown in detail here) and to read the RFID chips of the interposers. Here, the interposers are located on a PET strip having a thickness of 50 μm. By way of example, such strips may contain four rows of RFID interposers. The coupling capacitor surfaces may be arranged as copper surfaces on the substrate 10.

The size of the copper surfaces, which can be referred to as pads, preferably corresponds to the size of the metallised connection surfaces of the interposers or straps. These pads are arranged directly on the surface of the substrate 10, which is designed as a PCB, wherein there is precise alignment between the coupling capacitor surfaces and the connection surfaces.

A number of pads can be actuated by a common reading and/or writing unit by means of high-frequency signal data, in order to move them into a capacitive coupling with the associated connection surfaces. In such a case, switching between the individual pads can take place by means of a multiplexer which is arranged in the control device, so that a common reading and writing unit can be used to read a plurality of interposers in temporal succession without any displacement of the interposers with respect to the test device arranged therebelow being necessary for this.

By means of vacuum channels 13a, 13b which pass through the test device, the underside of the interposer substrate 8 can be sucked onto the top surface of the test device and released again in a fast and simple manner in order to displace the interposer substrate 8 with the plurality of interposers arranged thereon with respect to the test device arranged below it. A test procedure can then take place in a further section of the interposer substrate. Of course, the test device can alternatively be displaced with respect to the interposer substrate strip in order to test a new region of the interposer substrate strip.

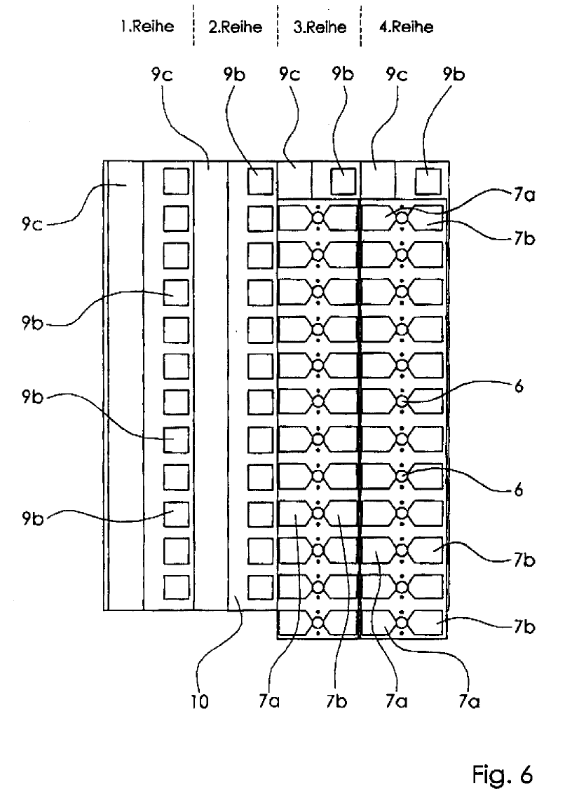

FIG. 6 shows, in a plan view, the embodiment of the test apparatus shown in FIG. 5. It can clearly be seen from this diagram that there are a total of four rows of interposers arranged one behind the other. In this case, the rows of pads are joined together to form a linear longer coupling capacitor surface 9c, so as to obtain for example a common ground potential for a plurality of interposer connection surfaces. In this case, the high-frequency energy of the writing and reading unit is passed individually via switching stages to the pads 9b lying opposite. Then always just one pair of pads 9b, 9c assigned to an individual interposer is active per writing and/or reading unit. This activation may be carried out in temporal succession.

As an alternative, to increase the throughput of the production apparatus as a whole, a plurality of writing and/or reading units may be provided which check a plurality of interposers simultaneously. Advantageously, different operating frequencies are used in this case in order to avoid mutual interference.

Actuation of the coupling capacitor surfaces 9b, 9c may take place in a symmetrical or non-symmetrical manner with respect to the ground potential 9c. The signal difference between the pads serves as an HF energy source and communication channel for the RFID chip on the interposer. In order to reduce coupling losses of the capacitive coupling at the capacitor plates formed in the structure, symmetry devices and impedance converter stages can be used to increase the source resistance for the capacitor coupling surfaces on the substrate 10. Improved matching conditions between the interposer and the capacitor coupling surfaces can thus be achieved.

The plan view of the test apparatus which is shown in FIG. 6 has the individual pads 9b separated from one another, with switching taking place by means of a multiplexer in such a way that a test procedure on the individual interposers is carried out in temporal succession for each row and in each case from top to bottom.

All the features disclosed in the application documents are claimed as essential to the invention in so far as they are novel individually or in combination with respect to the prior art.

### LIST OF REFERENCES

1, 2 capacitors
3, 4 resistances
5 capacitor
6 RFID chips
7a, 7b connection surfaces
8 interposer substrate
9a, 9b coupling capacitor surfaces
10 substrate
11 adhesive layer or adhesion auxiliary layer
12 control device
13a, 13b vacuum channels

### Key to Figures

1. Reihe=1st row
2. Reihe=2nd row
3. Reihe=3rd row
4. Reihe=4th row

1. A test method for testing a large number of RFID interposers in order to check their functionality by means of a test device, the method comprising:
providing a plurality of interposers, wherein each interposer comprises at least one RFID chip and at least two connection surfaces which are arranged on an interposer substrate and are connected to the RFID chip, the connection surfaces which are arranged on the interposer substrate are, as compared with the RFID chip, are significantly larger than connection surfaces of the at least one RFID chip, electrically conductive and capable for contacting a RFID antenna; and
providing a capacitive coupling for transmitting data for testing each interposer, the capacitive coupling is set up between the test device and at least one of the interposers and wherein a respective connection surface and a respective coupling capacitor surface having essentially the same dimensions are arranged opposite one another and parallel to one another in order to form a respective capacitor.

2. The method according to claim 2, wherein the capacitive coupling is set up between the connection surfaces on the one hand and electrically conductive coupling capacitor surfaces arranged in the test device on the other hand.

3. The method according to claim 2, characterised in that at least one of the interposer substrates is arranged between the connection surfaces and the coupling capacitor surfaces.

4. The method according to claim 2, wherein the test device has a large number of coupling capacitor surfaces on which the large number of interposers are arranged, wherein the capacitors formed from the coupling capacitor surfaces and the connection surfaces are actuated by high-frequency RFID signal data received and/or transmitted by at least one reading and/or writing unit in order to communicate with the RFID chips of the interposers in succession and/or simultaneously.

5. An apparatus for testing a large number of RFID interposers, the apparatus comprising:
a pluarality of interposers, wherein each interposer comprises at least one RFID chip and at least two connection surfaces being significantly larger in area than connection surfaces of the at least one RFID chip wherein the connection surfaces are arranged on an interposer substrate and are connected to the RFID chip;
a test device; and
a capacitive coupling for transmitting data, the capacitive coupling is set up between the test device and at least one of the interposers at the connections surfaces.

6. The apparatus according to claim 5, wherein the test device has a layer structure composed of a control device, at least one plate-shaped substrate arranged thereon and coupling capacitor surfaces arranged on the substrate, wherein at least one interposer is arranged on the coupling capacitor surfaces with the interposer substrate facing towards the coupling capacitor surfaces.

7. The apparatus according to claim 5, wherein the interposers can be fixed on the test device by being subjected to a vacuum by means of a vacuum device.

8. The apparatus according to claim 6, wherein the test device comprises at least one reading and/or writing unit for receiving and/or transmitting signal data from and/or to the RFID chips of the interposers.

9. The apparatus according to claim 8, wherein the plate-shaped substrate has a large number of coupling capacitor surfaces on which the large number of interposers are placed, wherein the data of the RFID chips of the interposers can be read and/or written to in succession and/or at least partially simultaneously by means of the control device and the reading and/or writing units.
